(19) United States
(12) Patent Application Publication
(10) Pub. No.: US 2025/0158568 A1
(43) Pub. Date: May 15, 2025

(54) METHODS AND SYSTEMS FOR PHOTOVOLTAIC PANEL POWER CONTROL

(71) Applicant: NeoGenesys, Inc., Holly Ridge, NC (US)

(72) Inventor: Randall Douglas THOMPSON, North Topsail Beach, NC (US)

(21) Appl. No.: 18/948,928

(22) Filed: Nov. 15, 2024

Related U.S. Application Data
(60) Provisional application No. 63/598,996, filed on Nov. 15, 2023.

(51) Int. Cl. H02S 50/10; G02F 1/13; G02F 1/1335; H01L 31/054

(52) U.S. Cl. CPC H02S 50/10; G02F 1/1313; G02F 1/133512; H10F 77/42

(57) ABSTRACT

Methods and systems for photovoltaic (PV) panel power control are disclosed. In an aspect, a PV panel comprises one or more PV cells wired in parallel and/or in series to produce an output voltage, and a controllable-opacity layer disposed on the sunward-facing surface of the PV cell, wherein in a transparent mode, photons pass through the controllable-opacity layer to reach the one or more PV cells, and wherein in an opaque mode, photons are restricted from passing through the controllable-opacity layer to reach the one or more PV cells. In an aspect, a method for PV panel power control comprises determining that a PV panel is in an error condition or dangerous state, and controlling a controllable-opacity layer associated with the PV panel to an opaque state to block photons from reaching the PV panel.

### CROSS-REFERENCE TO RELATED APPLICATION

This application claims priority to U.S. Provisional Patent Application No. 63/598,996, filed Nov. 15, 2023, entitled “METHODS AND SYSTEMS FOR PHOTOVOLTAIC PANEL POWER CONTROL,” which is assigned to the assignee hereof and is expressly incorporated herein by reference in its entirety.

### TECHNICAL FIELD

This disclosure relates to monitoring and controlling photovoltaic panels. More specifically, it relates methods and systems for photovoltaic panel power control.

### BACKGROUND

Photovoltaic (PV) arrays, commonly referred to as “Solar Panels” are rapidly gaining adoption worldwide. The nature of these devices is to produce power in the form of electrons whenever exposed to visible light (photons). A typical semiconductor PV cell produces nominally 0.58 volts DC. A PV panel may comprise one or more PV cells. The PV cells are typically arranged in arrays of 96 elements and connected in series to produce output voltages of up to 32V nominal and 55V peak at 10 amps constant current. Multiple panels are then also connected in series. Each group of panels connected in series is referred to as a “string” and has an output voltage equal to the sum of the group's panels. Strings typically consist of 10 panels or more, and typical voltage of a string is 320V/560V at 10 amps, or 3200 W/5600 W power.

Problems arise when poor workmanship or faulty components produce short circuits or expose the inter-panel connections to the environment in such a way as to create a short circuit arc to ground. Such electrical arcs can create a fire hazard, e.g., igniting ground cover, melting wiring insulation, etc., and may result in further, potentially catastrophic damage to not only the faulty component but also to other equipment in the vicinity or even to an entire facility if the fire spreads.

Breaking a high-power DC circuit is not easily accomplished as the panels continue to produce power for so long as they are exposed to sunlight, irrespective of the condition of the circuit to which they are connected. Electro-mechanical devices known as interrupters exist for this purpose but are expensive and bulky and so not practical as a solution. Accordingly, there is a need for improved methods and systems for PV panel control.

### SUMMARY

The subject matter disclosed herein includes methods and systems for photovoltaic (PV) panel power control.

In an aspect, a PV panel comprises one or more PV cells wired in parallel and/or in series to produce an output voltage, and a controllable-opacity layer disposed on the sunward-facing surface of the PV cell, wherein in a transparent mode, photons pass through the controllable-opacity layer to reach the one or more PV cells, and wherein in an opaque mode, photons are restricted from passing through the controllable-opacity layer to reach the one or more PV cells.

In an aspect, a method for PV panel power control comprises determining that a PV panel is in an error condition or dangerous state, and controlling a controllable-opacity layer associated with the PV panel to an opaque state to block photons from reaching the PV panel.

In an aspect, a PV panel power control apparatus comprises a memory and at least one processor communicatively coupled to the memory. The at least one processor is configured to determine that a PV panel is in an error condition or dangerous state, and control a controllable-opacity layer associated with the PV panel to an opaque state to block photons from reaching the PV panel.

The subject matter described herein may be implemented in hardware, software, firmware, or any combination thereof. As such, the terms “function” or “module” as used herein refer to hardware, software, and/or firmware for implementing the feature being described. In one exemplary implementation, the subject matter described herein may be implemented using a computer readable medium having stored thereon executable instructions that when executed by the processor of a computer control the computer to perform steps. Exemplary computer readable media suitable for implementing the subject matter described herein include disk memory devices, chip memory devices, programmable logic devices, application specific integrated circuits, and other non-transitory storage media. In one implementation, the computer readable medium may include a memory accessible by a processor of a computer or other like device. The memory may include instructions executable by the processor for implementing any of the methods described herein. In addition, a computer readable medium that implements the subject matter described herein may be located on a single device or computing platform or may be distributed across multiple physical devices and/or computing platforms.

### BRIEF DESCRIPTION OF THE DRAWINGS

Embodiments of the subject matter described herein will now be explained with reference to the accompanying drawings, wherein the like reference numerals represent like parts, of which:

FIG. 1A illustrates an exemplary installation incorporating photovoltaic (PV) panel power control according to an aspect of the disclosure;

FIG. 1B illustrates an example of PV panel power control in response to a fault condition of a PV panel according to an aspect of the disclosure;

FIGS. 2A and 2B are cross-sectional views of a solar panel and a controllable-opacity layer according to different aspects of the disclosure;

FIG. 3 is a block diagram of an exemplary hardware module for performing a function described herein; and

FIG. 4 is a flow chart illustrating an exemplary process for PV panel power control according to an aspect of the disclosure.

### DETAILED DESCRIPTION

Methods and systems for photovoltaic (PV) panel power control are provided herein. In an aspect, a controllable-opacity layer is disposed between the PV power-generating material (e.g., one or more semiconducting PV cells) and the sun. In an aspect, the controllable-opacity layer may comprise a mylar thin-film liquid crystal display (LCD) with variable opacity from transparent to opaque according to a control voltage. In an aspect, the controllable-opacity layer completely covers the sun-facing surface of the solar panel. In an aspect, the opacity of the controllable-opacity layer may be controlled by control circuitry, such as a low-power embedded microcontroller. The controllable-opacity layer functions to block photons from reaching the PV cell, which causes the PV cell to stop producing power. In this manner an individual PV cell may be effectively “turned off”.

In some aspects, the control circuitry may monitor the operational condition of a PV cell, the environment in which the PV cell is operating, or other indicia, and set the opacity of the controllable-opacity layer accordingly. For example, in addition to controlling the controllable-opacity layer, the microcontroller can also be used to provide real-time measurement of key voltages and temperatures of the solar panel and report this data via wireless mesh network to a supervisory control and data acquisition (SCADA) system or other control system. For example, in some aspects, in the event of a short circuit or over-temperature condition the SCADA system may then command all affected panels to go opaque and stop producing power. This will terminate the power flow to the affected areas and allow maintenance crews to effect repairs without risk of electrocution.

In some aspects, the controllable-opacity layer may be opaque in its unpowered state. If the controller does not have a power supply separate from the PV panel that it is controlling, then at night, when the PV panel turns off, the controller also loses power, and the controllable-opacity layer will resort to its opaque unpowered state. If the unpowered state of the controllable-opacity layer is such that all photons are blocked from reaching the PV panel, then the PV panel may continue to generate no power even during the daytime, the controller never gets power, and so the controllable-opacity layer never changes from its opaque unpowered state. In some aspects, the controller may include an independent power source sufficient to operate the microcontroller during periods where power cannot be drawn from the solar panel's array. In some aspects, the independent power source could be a separate dedicated PV array paired with a supercapacitor, a 10-year battery, or other external power source. In some aspects, a small portion of the PV panel may remain uncovered by the controllable-opacity layer to provide sufficient power to operate the microcontroller during daylight hours, so that after sunrise the PV panel powers the microcontroller, which then controls the opacity of the covered portion of the PV panel as needed.

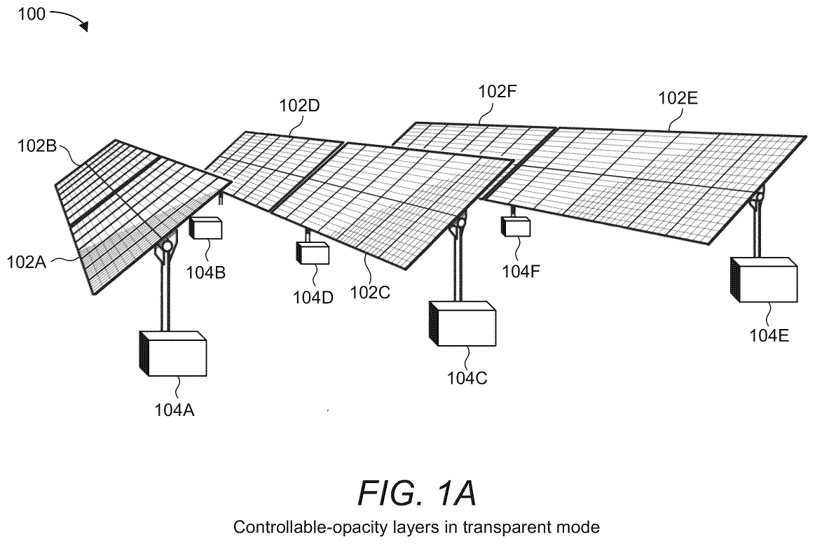

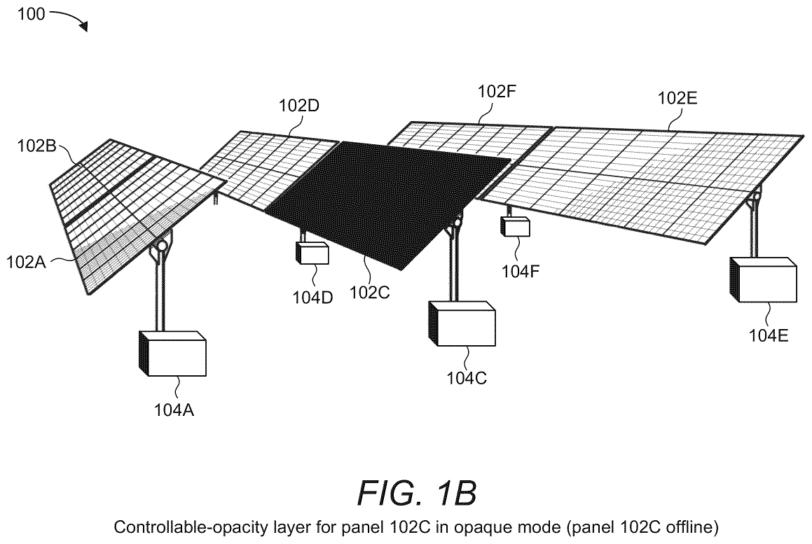

FIG. 1A illustrates an exemplary installation 100 incorporating photovoltaic panel power control according to an aspect of the disclosure. According to one aspect, the installation 100 includes a set of PV panels, labeled 102A-F, which may be collectively referred to as panels 102 or individually as panel 102A, panel 102B, etc. Each of the panels 102 include a controllable-opacity layer. In the example illustrated in FIG. 1A, each of the panels 102 has its own power controller, labeled 104A for panel 102A, 104B for panel 102B, etc., which may be collectively referred to as power controllers 104 or individually as power controller 104A, power controller 104B, etc. In the example shown in FIG. 1A, each of the power controllers 104 controls the state of the controllable-opacity layer for its associated panel 102. In another aspect, a single controller may control the controllable-opacity layer for multiple panels 102. In the example shown in FIG. 1A, the controllable-opacity layer for each of the multiple panels 102 is set to a transparent mode.

FIG. 1B illustrates an example response to a fault condition of panel 102C according to an aspect of the disclosure. In the example shown in FIG. 1B, the controllable-opacity layer of panel 102C has been set to an opaque mode, which blocks the sunlight from reaching the PV material of the panel 102C. As a result, the power output by the panel 102C stops or is significantly reduced. In some aspects, the output voltage of the panel 102C drops to zero volts or is otherwise significantly reduced. In the example shown in FIG. 1B, the state of the controllable-opacity layer of panel 102C is controlled by the controller 104C. It will be understood that the opaque mode is ideally fully opaque, i.e., allowing no photons to pass through to the PV material beneath, but depending on the material of which the controllable-opacity layer is made, the opaque mode may not block all photons completely but may instead allow some smaller number of photons to reach the PV material. In some aspects, the controllable-opacity layer of a panel 102 may be divided into individually-controllable zones. For example, when a PV panel is comprised of a plurality of PV cells, the controllable-opacity layer may be subdivided into a plurality of zones, e.g., one zone per PV cell, so that photons may be blocked from individual PV cells within the PV panel.

Examples of fault conditions include, but are not limited to: an electrical short within the panel 102C or within electrical connections to and from the panel 102C; electrical arcing within the panel 102C or from the panel 102C to ground, to another panel, to mounting hardware, within a terminal box or other electrical equipment near to or associated with the panel 102C; a high-temperature condition detected within the panel 102C, an electrical or mechanical connection to the panel 102C, or the environment in which the panel 102C is located; a fire or combustion of the panel 102C, another panel, the ground cover below or near the panel 102C, or other electrical equipment in proximity to the panel 102C; an erratic or unexpected power output by the panel 102C; and so on.

In some aspects, the controller 104C may also detect the fault condition. For example, the controller 104C may communicate with temperature sensors, smoke sensors, fire sensors, light or video sensors (to detect arcing), electrical sensors to detect dangerous voltages or currents, microphones or audio sensors to detect sounds of sparks, arcs, or fire, and so on. In some aspects, the controller 104C may receive an instruction to disable the panel 102C from another entity, which may have been the entity to detect the fault condition or an entity through which instructions are communicated to the controllers 104 or to the controller 104C specifically in response to detection of the fault condition by some other entity.

In some aspects, the controllable-opacity layer of a panel, such as panel 102C in FIG. 1B, may be set to an opaque mode for reasons other than in response to a fault condition of the panel 102C. Examples of other reasons include, but are not limited to: scheduled maintenance of the panel 102C; repair, replacement, reconfiguration, and/or relocation of the panel 102C; any other kind of service to the panel 102C; and/or any of the above-listed reasons as applied to another panel which is in proximity to the panel 102C or is associated with the panel 102C in some way. That is, a panel may be put into a photon-blocking or reduced power state in order to perform some maintenance or service on another panel that is electrically or physically connected to the panel 102C in some way.

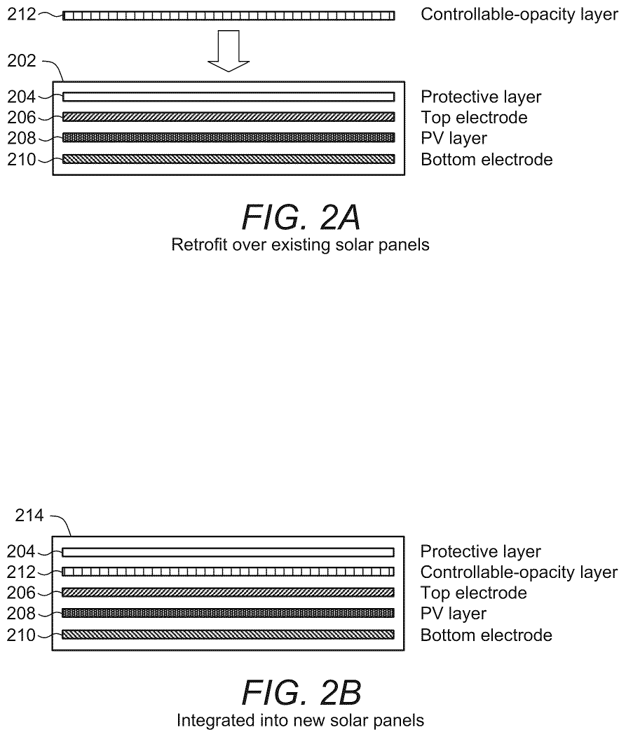

FIGS. 2A and 2B are cross-sectional views of a solar panel and a controllable-opacity layer according to different aspects of the disclosure. In FIG. 2A, a conventional PV panel 202 comprises a transparent, protective layer 204 that covers a PV cell that includes at least one top electrode 206, PV layer 208, and bottom electrode 210. In FIG. 2A, a controllable-opacity layer 212 is mounted to the sun-facing surface of the conventional PV panel 202. When the controllable-opacity layer 212 is set to a transparent mode, photons can pass through the controllable-opacity layer 212 and the protective layer 204 to reach the PV layer 208 and generate an output voltage across the top electrode 206 and the bottom electrode 210. When the controllable-opacity layer 212 is set to an opaque mode, photons are blocked from reaching the conventional PV panel 202 below the controllable-opacity layer 212, and therefore the conventional PV panel 202 does not generate an output voltage. In FIG. 2B, the controllable-opacity layer 212 may be integrated within an improved PV panel 214, e.g., below the protective layer 204 and the above the top electrode 206, PV layer 208, and bottom electrode 210. It will be understood that the layers of the simplified PV panels shown in FIGS. 2A and 2B are for illustration purposes only and are not limiting. For example, the conventional PV panel 202 and the improved PV panel 214 may have different numbers of photosensitive layers, electrodes, dielectrics, and so on, and those layers may be in different orders. It will be understood that a PV panel may include multiple different PV layers. It will be further understood that a multi-layer PV panel may have multiple controllable-opacity layers, e.g., one above each PV layer in the stack of PV layers that make up the multi-layer PV panel, and that the controllable-opacity layers may be controlled individually or in groups.

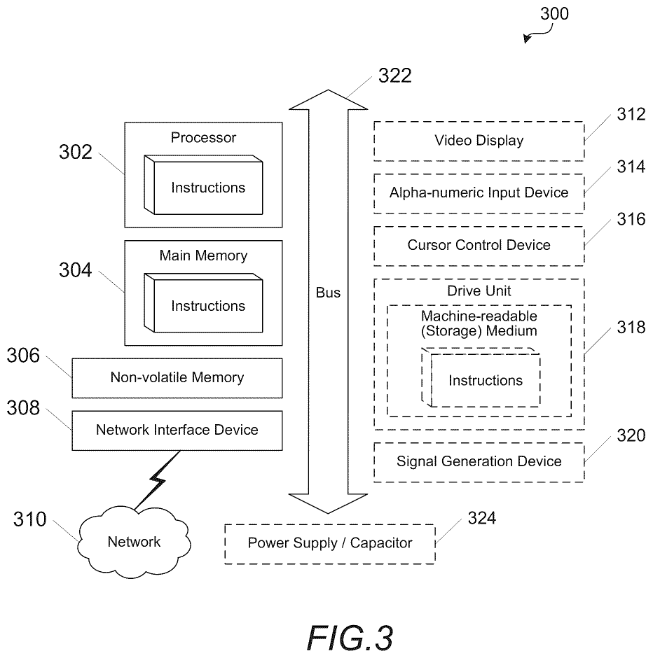

FIG. 3 is a block diagram of an exemplary system 300 for performing a function described herein. In the embodiment illustrated in FIG. 3, the system 300 may include a processor 302 that executes instructions that may be stored locally and that may be fetched from main memory 304. Main memory may be volatile, non-volatile, or a combination of the two. In some aspects, the system 300 may include non-volatile memory 306, such as ROM, EPROM, EEPROM, FLASH, and the like. In some aspects, the system 300 may include a network interface device 308 for communicating over a network 310.

In some aspects, the system 300 may include optional components, such as a video display 312, which may be used to provide a graphic user interface (GUI) to a user, an alphanumeric input device 314, such as a keyboard, and a cursor control device 316, such as a mouse, pointer, stylus, touch screen, etc. In some aspects, the system 300 may include mass storage, such as a hard disk drive or solid state drive 318, which may be used to store instruction code. In some aspects, the system 300 may include a signal generation device 320 or other peripheral for communicating with or controlling external devices. In some aspects, the modules of the system 300 may communicate with each other via one or more busses 322. In some aspects, the system 300 may include its own power supply 324, which may comprise a battery, a capacitor, a solar cell, or other power source

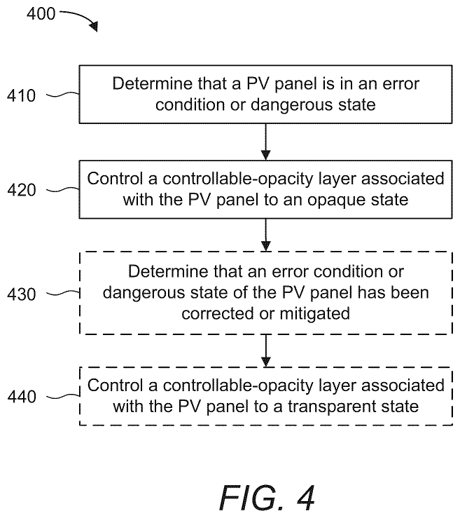

FIG. 4 is a flow chart illustrating an exemplary process 400 for PV panel power control according to an aspect of the disclosure.

As shown in FIG. 4, process 400 may include, at block 410, determining that a PV panel is in an error condition or dangerous state.

As shown in FIG. 4, process 400 may include, at block 420, controlling a controllable-opacity layer associated with the PV panel to an opaque state.

As shown in FIG. 4, process 400 may optionally include, at block 430, determining that the error condition or dangerous state of the PV panel has been corrected or mitigated.

As shown in FIG. 4, process 400 may optionally include, at block 440, controlling the controllable-opacity layer associated with the PV panel to a transparent state.

The methods and systems disclosed herein may be implemented using hardware or hardware in combination with software and/or firmware. The functions described herein may be performed by one or more hardware modules.

The present disclosure contemplates at least the following embodiments:

Clause 1. A method for photovoltaic (PV) panel power control, the method comprising: determining that a PV panel is in an error condition or dangerous state; and controlling a controllable-opacity layer associated with the PV panel to an opaque state to block photons from reaching the PV panel.

Clause 2. The method of clause 1, further comprising: determining that the error condition or dangerous state of the PV panel has been corrected or mitigated; and controlling the controllable-opacity layer associated with the PV panel to a transparent state.

Clause 3. A photovoltaic (PV) panel, comprising: one or more PV cells wired in parallel and/or in series to produce an output voltage; and a controllable-opacity layer disposed on the sunward-facing surface of the PV cell, wherein in a transparent mode, photons pass through the controllable-opacity layer to reach the one or more PV cells, and wherein in an opaque mode, photons are restricted from passing through the controllable-opacity layer to reach the one or more PV cells.

Clause 4. The PV panel of clause 3, wherein the opacity of the controllable-opacity layer is controlled by a control signal received at a control signal input.

Clause 5. The PV panel of clause 4, wherein the opacity of the controllable-opacity layer is controlled by a control voltage received at the control signal input.

Clause 6. The PV panel of any of clauses 3 to 5, wherein the controllable-opacity layer comprises a mylar thin-film liquid crystal display (LCD).

Clause 7. An apparatus for PV panel power control, the apparatus comprising a memory and at least one processor communicatively coupled to the memory. The at least one processor is configured to determine that a PV panel is in an error condition or dangerous state, and control a controllable-opacity layer associated with the PV panel to an opaque state to block photons from reaching the PV panel.

Clause 8. The apparatus of clause 7, wherein, to control the controllable-opacity layer associated with the PV panel to an opaque state, the at least one processor is configured to generate a first control signal to be provided to the controllable-opacity layer associated with the PV panel.

Clause 9. The apparatus of clause 8, wherein the first control signal comprises a first control voltage, a first control current, or a first control message.

Clause 10. The apparatus of any of clauses 7 to 9, wherein the at least one processor is further configured to: determine that the error condition or dangerous state of the PV panel has been corrected or mitigated; and control the controllable-opacity layer associated with the PV panel to a transparent state.

Clause 11. The apparatus of clause 10, wherein, to control the controllable-opacity layer associated with the PV panel to a transparent state, the at least one processor is configured to generate a second control signal to be provided to the controllable-opacity layer associated with the PV panel.

Clause 12. The apparatus of clause 11, wherein the second control signal comprises a second control voltage, a second control current, or a second control message.

1. A method for photovoltaic (PV) panel power control, the method comprising:
determining that a PV panel is in an error condition or dangerous state; and
controlling a controllable-opacity layer associated with the PV panel to an opaque state to block photons from reaching the PV panel.

2. The method of claim 1, further comprising:
determining that the error condition or dangerous state of the PV panel has been corrected or mitigated; and
controlling the controllable-opacity layer associated with the PV panel to a transparent state.

3. A photovoltaic (PV) panel, comprising:
one or more PV cells wired in parallel and/or in series to produce an output voltage; and
a controllable-opacity layer disposed on a sunward-facing surface of the PV cell, wherein in a transparent state, the controllable-opacity layer allows photons pass through the controllable-opacity layer to reach the one or more PV cells, and wherein in an opaque state, the controllable-opacity layer restricts or prevents photons from passing through the controllable-opacity layer to reach the one or more PV cells.

4. The PV panel of claim 3, wherein an opacity of the controllable-opacity layer is controlled by a control signal received at a control signal input.

5. The PV panel of claim 4, wherein the opacity of the controllable-opacity layer is controlled by a control voltage received at the control signal input.

6. The PV panel of claim 3, wherein the controllable-opacity layer comprises a mylar thin-film liquid crystal display (LCD).

7. An apparatus for photovoltaic (PV) panel power control, the apparatus comprising:
a memory; and
at least one processor communicatively coupled to the memory, the at least one processor configured to:
determine that a PV panel is in an error condition or dangerous state; and
control a controllable-opacity layer associated with the PV panel to an opaque state to block photons from reaching the PV panel.

8. The apparatus of claim 7, wherein, to control the controllable-opacity layer associated with the PV panel to the opaque state, the at least one processor is configured to generate a first control signal to be provided to the controllable-opacity layer associated with the PV panel.

9. The apparatus of claim 8, wherein the first control signal comprises a first control voltage, a first control current, or a first control message.

10. The apparatus of claim 7, wherein the at least one processor is further configured to:
determine that the error condition or dangerous state of the PV panel has been corrected or mitigated; and
control the controllable-opacity layer associated with the PV panel to a transparent state.

11. The apparatus of claim 10, wherein, to control the controllable-opacity layer associated with the PV panel to the transparent state, the at least one processor is configured to generate a second control signal to be provided to the controllable-opacity layer associated with the PV panel.

12. The apparatus of claim 11, wherein the second control signal comprises a second control voltage, a second control current, or a second control message.
